(19) United States
(12) Patent Application Publication
(10) Pub. No.: US 2021/0167072 A1
(43) Pub. Date: Jun. 3, 2021

(54) 3D MEMORY DEVICE COMPRISING SRAM TYPE MEMORY CELLS WITH ADJUSTABLE BACK-BIAS

(71) Applicant: COMMISSARIAT A L'ENERGIE ATOMIQUE ET AUX ENERGIES ALTERNATIVES, Paris (FR)

(72) Inventors: Adam MAKOSIEJ, Grenoble Cedex 09 (FR); Bastien GIRAUD, Grenoble Cedex 09 (FR); Jean-Philippe NOEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/109,227

(22) Filed: Dec. 2, 2020

(30) Foreign Application Priority Data
Dec. 3, 2019 (FR) 19 13651

(51) Int. Cl. H01L 27/11; H01L 29/78

(52) U.S. Cl. CPC H01L 27/1116; H01L 29/7838; H01L 27/1104

(57) ABSTRACT

A memory device including a matrix of memory cells including FET transistors including back-bias elements, of which at least one column forms back-bias bits; a back-bias circuit outputting voltages dependent on back-bias bits; first and second coupling elements, coupling memory dots of back-bias bits with the back-bias circuit, and the back-bias circuit with the back-bias elements of the cells of the matrix; wherein the device forms a 3D circuit including first and second active layers between which several interconnection layers are stacked; the first and/or the second coupling elements include metallic portions of one of the interconnection layers.

### TECHNICAL FIELD

This document relates to a 3D (three-dimensional) memory device, in other words made in the form of a circuit comprising several active layers, or several levels of electronic components, superposed, and comprising memory cells. It may be applied to devices forming one or several SRAM (“Static Random Access Memory”) memories, but also to devices forming one or several CAM (“Content-Addressable Memory”), TCAM (“Ternary Content-Addressable Memory”) or DRAM (“Dynamic Random Access Memory”) or ROM (“Read Only Memory”) memories.

### State of Prior Art

For manufacturing of memory devices comprising memory cells such as SRAM type memory cells, it is advantageous to use FET (“Field-Effect Transistor”) transistors for which the back-bias can be adjusted. With such transistors used to form memory cells, the performance/electrical consumption ratio of memory cells can be adjusted as a function of needs and constraints imposed on the memory devices. Back-bias control bits, the values of which are representative of the back-bias voltage levels to be applied to transistors, are generally stored in latches or toggles, or OTP (“One Time Programmable”)/MTP (“Multi time Programmable”) cells to enable fast access to these bits. The problem that arises is that these elements occupy a large surface area on the active layer, which limits the number of latches, toggles or cells that can be made considering the small available surface area of the active layer in the memory device. Consequently, this prevents the production of a memory device in which the back-bias of memory cell transistors would be adjusted for each memory cell.

Furthermore, in standard memory devices comprising memory cells made using the CMOS technology, in other words comprising MOSFET transistors, the doped semiconducting wells of transistors to which bias voltages are applied are such that each well is common to all memory cells in a single column, and possibly common to memory cells in two adjacent columns. An embodiment of doped semiconducting wells in which each well is common to all memory cells in a row is possible, but this causes an increase of the surface area occupied by each of the memory cells. In all cases, these well configurations limit the possibilities of adjusting back-bias voltages of memory cell transistors.

### PRESENTATION OF THE INVENTION

Thus there is a need to propose a memory device in which an adjustable back-bias of memory cell transistors is applied efficiently, in other words without significantly increasing the occupied surface area of the active layer and electrical consumption.

To achieve this, a memory device is disclosed, comprising at least:
a matrix of several rows and columns of memory cells forming data memorization bits, each of the memory cells comprising FET transistors including at least one electrically conducting back-bias element, the matrix also comprising at least one column of memory cells forming first back-bias control bits;
a first back-bias circuit configured to output first back-bias voltages, the values of which depend on the values of first back-bias control bits;
first coupling elements, electrically coupling memory dots of memory cells forming the first back-bias control bits with the first back-bias circuit;
second coupling elements, electrically coupling the first back-bias circuit with electrically conducting back-bias elements of memory cells forming the data storage bits;

and wherein
the memory device forms a 3D circuit comprising at least first and second semiconducting active layers between which several metallic interconnection layers are stacked;
the matrix of memory cells is made in the second active layer, and the first back-bias circuit is made in at least one of the first and second active layers;
the first and/or the second coupling elements comprise metallic portions of at least one of the metallic interconnection layers.

A precise correction of memorization, read and/or write, or data comparison operations can be made with such a memory device, by choosing appropriate values of back-bias voltages, these values being defined by values memorized in the first back-bias control bits.

For example, a read or write operation carried out in one or several rows of memory cells that are too slow relative to the other rows of memory cells can be locally accelerated, and/or such an operation performed in one or several rows of memory cells that are too fast relative to the other rows of memory cells can be slowed, thus obtaining good performances with minimum electrical consumption. This corresponds to the case of a static bias in which a constant bias is applied independently for each row of memory cells during an active operation or standby mode of the memory device. A selective and static bias can also be made, different for active and standby modes, and that changes globally, in other words for all memory cells, between these modes depending on bias states.

With this memory device, one suitable back-bias state among several possible back-bias states can also be chosen for one or several memory cells and independently of other memory cells, depending on the operation to be performed. These bias states can be applied independently for each row of memory cells, depending on the required consumption/performance ratio.

Production of the memory device in the form of a 3D circuit makes it possible to use metallic interconnection layers located between the first and second active layers to form the first and/or second coupling elements. This configuration is advantageous because it has no effect on the architecture of the memory device or its functions because it does not add any capacitive coupling to signals of the memory circuit.

Furthermore, production of the memory device in the form of a 3D circuit makes it possible to make connections to electrically conducting back-bias elements of memory cell transistors that are independent for each transistor or for several transistors, in a memory cell, without occupying any surface area.

Furthermore, with this memory device there may be several values of back-bias voltages, so that good flexibility can be obtained in adjusting the operating point of the memory device as a function of the required consumption/performance ratio.

The states of the first back-bias control bits may be used as control values for the first back-bias circuit that then generates the bias voltages with values defined by the states of the first back-bias control bits, or may be used as selection values used to choose one of several bias values (that may correspond to only the power supply voltage VDD and the ground) supplied as input to the first back-bias circuit.

The memory cells of the matrix may be of the SRAM, or CAM, or TCAM, or DRAM, or ROM type. In general, each memory cell comprises at least one memorization element (for example two inverters with FET transistors coupled crosswise for an SRAM, CAM or TCAM type memory cell, or a capacitor for a DRAM type memory cell, or other types of elements for non-volatile memory cells) to store and maintain data, and at least one FET transistor used to access the memorization element and/or to make a data comparison.

The memory device may be such that:
the first coupling elements comprise metallic portions of one of the metallic interconnection layers called the last metallic interconnection layer and that corresponds to the layer among said metallic interconnection layers that is closest to the second active layer, and the second coupling elements comprise metallic portions of one of the metallic interconnection layers called the penultimate metallic interconnection layer and that is arranged between the last metallic interconnection layer and all the other metallic interconnection layers, or
the first and second coupling elements comprise metallic portions of the last metallic interconnection layer.

The choice between the two configurations mentioned above may depend particularly on the number of coupling elements associated with each row of memory cells, and the number of first back-bias control bits associated with each row of memory cells.

Advantageously, the electrically conducting back-bias elements may be independent from one row of memory cells to the next. Thus, independent back-bias voltages can be applied for each row of memory cells.

The electrically conducting back-bias elements may comprise doped semiconducting wells. The device may also comprise several word lines such that the memory cells forming the data memorization bits and arranged on the same row of the matrix comprise access transistors, the gates of which are coupled to the same word line, and the semiconducting wells doped with the same type of conductivity and included in the transistors of memory cells in the same row of the matrix may be electrically coupled to each other and to at least one output of the first back-bias circuit by at least one of the second coupling elements such that the same back-bias voltage can be applied on said doped semiconducting wells.

The first back-bias control bits may be formed by memory cells in one or several adjacent columns forming a first edge of the matrix, adjacent to which the first back-bias circuit is located. Such a configuration can minimize the overload per unit area related to the storage of these first back-bias control bits.

The memory device may be such that:
the memory cells of at least one column forming a second edge of the matrix that is opposite the first edge of the matrix correspond to end of read control bits, the access transistors of which are coupled to at least one word line distinct from that to which the access transistors of the memory cells forming the memorization bits are coupled;
the memory cells forming the end of read control bits are electrically coupled to an end of read data memorization bits control circuit;
the semiconducting wells doped with the same type of conductivity and included in the transistors of memory cells forming the end of read control bits are electrically coupled to each other by third coupling elements comprising metallic portions of at least one of the metallic interconnection layers.

In the above configuration, the read time of data memorization bits can be adjusted optimally by measuring a read time obtained using the end of read control bits.

The metallic portions of the third coupling elements may correspond to portions of the same metallic interconnection layer as that or one of those forming the metallic portions of the first and/or second coupling elements.

The memory device may also include:
at least one inputs/outputs block to which the columns of memory cells forming the data memorization bits are electrically connected;
a second back-bias circuit configured to output second back-bias voltages, the values of which depend on the values of second back-bias control bits formed by at least one row of the matrix;
fourth coupling elements, electrically coupling the memory dots of memory cells forming the second back-bias control bits with the second back-bias circuit, and comprising metallic portions of the same metallic interconnection layer as that or one of those forming the metallic portions of the first and/or second coupling elements;

and in which the second back-bias circuit is coupled to electrically conducting back-bias elements of FET type transistors in the inputs/outputs block.

In the above configuration, the back-bias of transistors in the inputs/outputs block of the memory device can be precisely controlled. It is thus possible to optimize the operation of one or several of the following control circuits forming part of the inputs/outputs block: read amplifiers, precharge circuits, write drivers, column multiplexers, etc.

The second back-bias control bits may be formed by memory cells in one or several adjacent rows forming a third edge of the matrix, adjacent to which the second back-bias circuit is located.

The third coupling elements may electrically couple the electrically conducting back-bias elements of transistors of the memory cells of said at least one column forming the second edge of the matrix with the second back-bias circuit.

### BRIEF DESCRIPTION OF THE DRAWINGS

This invention will be better understood after reading the description of example embodiments given purely for information and that is in no way limitative, with reference to the appended drawings on which:

FIG. 1 diagrammatically shows a first embodiment of a memory device;

FIG. 2 diagrammatically shows a sectional view of a part of the memory device, made in the form of a 3D circuit;

FIGS. 3 and 4 diagrammatically show example embodiments of coupling elements of the memory device according to the first embodiment;

FIG. 5 shows an example embodiment of a memory cell of a memory device;

FIG. 6 shows an example embodiment of doped back-bias semiconducting wells of a memory cell of a memory device;

FIG. 7 shows a particular example embodiment of doped semiconducting wells of transistors of four memory cells of a memory device;

FIG. 8 shows another particular example embodiment of doped semiconducting wells of transistors of four memory cells of a memory device;

FIGS. 9 to 11 show several example embodiments of the memory device according to the first embodiment;

FIG. 12 diagrammatically shows a second embodiment of a memory device;

FIGS. 13 and 14 diagrammatically show example embodiments of coupling elements of the memory device according to the second embodiment;

FIG. 15 diagrammatically shows a third embodiment of a memory device;

FIG. 16 diagrammatically shows an example of coupling between four columns of memory cells and an inputs/outputs block of a memory device;

FIGS. 17 to 19 diagrammatically show example embodiments of coupling elements of the memory device according to the third embodiment.

Identical, similar or equivalent parts of the different figures described below have the same numeric references to facilitate comparison between the different figures.

The different parts shown on the figures are not necessarily all at the same scale, to make the figures more easily understandable.

The different possibilities (variants and embodiments) must be understood as not being mutually exclusive and can be combined with each other.

### DETAILED PRESENTATION OF PARTICULAR EMBODIMENTS

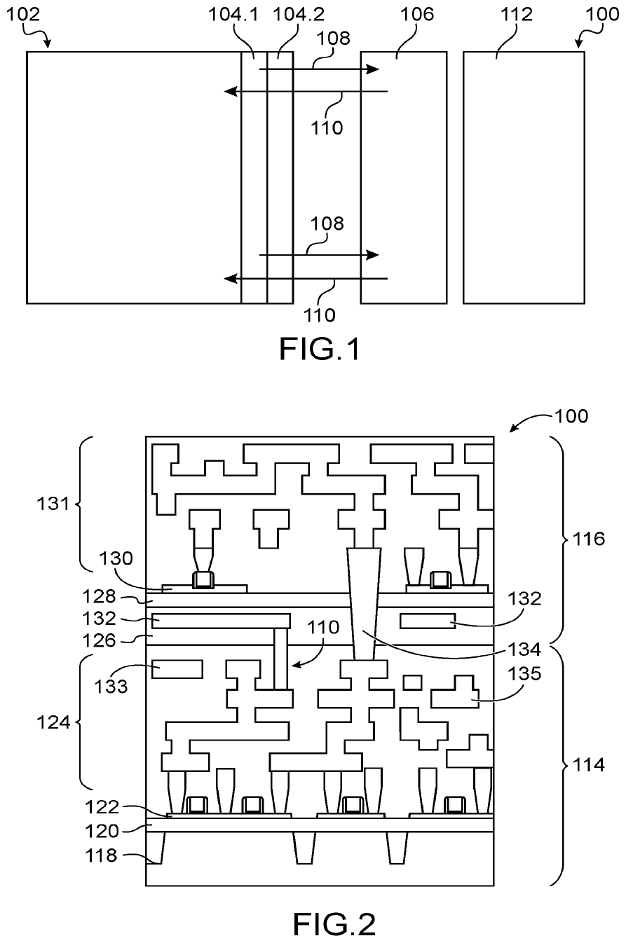

FIG. 1 diagrammatically shows a first embodiment of a memory device 100.

The memory device 100 comprises a matrix 102 of several rows and several columns of memory cells. In the first embodiment described herein, the memory cells are of the SRAM type. Each of the SRAM type memory cells may for example comprise 6 FET or MOSFET transistors (in this case called 6T-SRAM cell). As a variant, the memory cells of the matrix 102 may comprise more or less than 6 FET transistors. For example, the memory cells of the matrix 102 may correspond to the memory cells described in at least one of the following documents: “5T SRAM With Asymmetric Sizing for Improved Read Stability” by S. Nalam et al., IEEE Journal of Solid-State Circuits, Vol. 46, No. 10, October 2011; “An 8T-SRAM for Variability Tolerance and Low-Voltage Operation in High-Performance Caches” by L. Chang et al., IEEE Journal of Solid-State Circuits, Vol. 43, No. 4, April 2008; “A 32 kb 10T Sub-Threshold SRAM Array With Bit-Interleaving and Differential Read Scheme in 90 nm CMOS” by I. J. Chang et al., IEEE Journal of Solid-State Circuits, Vol. 44, No. 2, February 2009.

Each of the memory cells of the matrix 102 comprises N and P type FET transistors forming a memory dot, or internal node, in which a value corresponding to the low state or the high state of the bit formed by the memory cell is stored. Each memory cell of the matrix 102 also comprises access transistors each having their gate connected to a word line, on which a signal transits controlling a read or write access to memory cells receiving this signal. In the matrix 102, the access in write or read is made row by row, each word line being connected to the gates of access transistors of memory cells located on the same row of the matrix 102. The access transistors are also connected to bit lines on which data to be memorized in memory cells or data read from memory cells transit. The bit lines are common to memory cells located on the same column of the matrix 102, in other words each bit line is connected to memory cells located on the same column of the matrix.

The transistors of memory cells of the matrix 102 comprise electrically conducting back-bias elements, for example corresponding to doped semiconducting wells, forming ground planes and making back-bias of the transistors possible. These electrically conducting back-bias elements are located under the channel regions of these transistors. For example, the transistors of memory cells of the matrix 102 are of the FDSOI (“Fully-Depleted Silicon-On-Insulator”) type, and the doped semiconducting wells are located under buried dielectric portions located under the transistor channels.

The memory cells of the matrix 102 form data memorization bits in which data sent to the input of the device 100 are memorized.

The memory cells of one or several columns 104 of the matrix 102 do not correspond to data memorization bits, instead they correspond to back-bias control bits in which the back-bias states of the memory cells forming the data memorization bits are memorized. In the example embodiment shown on FIG. 1, two columns of memory cells referenced 104.1 and 104.2, are dedicated to memorization of these back-bias states.

The value coded in the back-bias control bit or bits of the i^{th} row of the matrix 102 is used to generate or to select a value of a back-bias voltage to be applied to the doped semiconducting wells of the transistors of memory cells forming data memorization bits and located on the i^{th} row of the matrix 102.

The memory device 100 also comprises a back-bias circuit 106 electrically connected to the matrix 102 and outputting back-bias voltages.

First coupling elements 108 electrically couple the memory dots of memory cells in columns 104 to inputs of the back-bias circuit 106. Second coupling elements 110 electrically couple outputs of the back-bias circuit 106 to the doped semiconducting wells of memory cells forming data memorization bits.

For each row of the matrix 102, depending on the binary value coded in the back-bias control bits for this row and read by the back-bias circuit 106 by means of the first coupling elements 108, the back-bias circuit 106 applies a bias voltage to the transistor wells of the memory cells forming the memorization bits of this row of the matrix 102, the value of which depends on the value coded in the back-bias control bits of this row of the matrix 102. Therefore the back-bias circuit 106 establishes a correspondence between the value coded in the back-bias control bits of a row of the matrix 102 and the value of the back-bias voltage applied on the doped semiconducting wells of transistors of the memory cells forming data memorization bits of this row of the matrix 102.

Thus, the memory device 100 comprises a matrix 102 of memory cells including transistors, the back-bias of which can be adjusted precisely and independently for each row of the matrix 102.

On the example embodiment shown on FIG. 1, each row of the matrix 102 comprises two back-bias control bits formed by the two memory cells of columns 104.1 and 104.2 located on this row. Thus, the binary value coded in the back-bias control bits can be one of four different values. Therefore with this configuration, for the transistors of the memory cells of each row of the matrix 102, a back-bias voltage can be applied for which the value corresponds to one of four possible values.

As a variant, each row of the matrix 102 may comprise only one back-bias control bit, in this case the matrix 102 comprising a single column 104. The value of the back-bias voltage applied on the transistors of the memory cells of each row of the matrix 102 is then chosen from among two possible values, for example corresponding to the ground GND and the power supply voltage VDD. In general, each row of the matrix 102 may comprise n back-bias control bits (in this case the matrix 102 comprising n columns 104), the value of the bias voltage applied on the transistors of the memory cells of each of the rows of the matrix 102 possibly being chosen from among 2″ possible values, in which n is an integer number greater than or equal to 1.

Values coded by back-bias control bits may vary from one row to another within the matrix 102, so that values of applied back-bias voltages can be independent from one row of memory cells of the matrix 102 to another.

According to one embodiment, the back-bias circuit 106 may comprise a multiplexer including transfer gates. In this case, the back-bias control bits may control the transfer gates of the multiplexer of the back-bias circuit 106 from which the back-bias voltages are outputted. Back-bias voltages may be generated within the back-bias circuit 106, or may be obtained from outside the back-bias circuit 106, in this case with the back-bias circuit 106 controlling selection of the value of the back-bias voltage to be applied for each of the rows of memory cells in the matrix 102.

On the example embodiment shown on FIG. 1, the memory cells forming the back-bias control bits correspond to memory cells of columns forming the right edge of the matrix 102. As a variant, the memory cells forming the back-bias control bits may correspond to the memory cells of one or several columns other than those shown on FIG. 1, for example those forming the left edge of the matrix 102.

The memory device 100 also comprises a word lines driver circuit 112 electrically connected to the word lines of the device 100 (not shown on FIG. 1) and that controls the read or write access in each row of the matrix 102 (to the memory cells forming data memorization bits and to the memory cells forming the back-bias control bits).

In the previously described device 100, if the entire matrix 102 is supplied between a power supply voltage V_{DD} and a reference potential GND, the values memorized in each bit of columns 104 statically correspond to one of the two potential values V_{DD} or GND, for example V_{DD} that corresponds to the high state and GND that corresponds to the low state. However, according to another example embodiment, it is possible that the electrical potentials used to electrically supply the memory cells of the columns 104 are different from those supplying the memory cells forming the data memorization bits. For example, the memory cells of column 104.1 may be powered between electrical potentials V_{DD1} and GND1 and the memory cells of column 104.2 may be powered between electrical potentials V_{DD2} and GND2, these values possibly being different from each other and different from the values of V_{DD} and GND supplying power to the memory cells forming the data memorization bits. However, the values of these electrical potentials are chosen such that the operating stability of the memory cells of columns 104 is unaffected.

The memory device 100 is made in the form of a 3D circuit comprising at least two superposed semiconducting active layers between which several metallic interconnection layers are stacked.

FIG. 2 diagrammatically shows a sectional view of a part of the device 100 comprising two superposed levels 114, 116 firmly secured to one another in the form of a 3D circuit.

The first level 114 is made with a first SOI substrate comprising a first support layer 118 comprising for example silicon, a first buried dielectric layer 120 comprising for example SiO₂ and a first semiconducting active layer 122, for example made of silicon. Electronic components, particularly FDSOI type FET transistors, are made in the first active layer 122 and form different circuits of the memory device 100: line decoder, read amplifiers, etc. Several metallic interconnection layers 124 are made above the first active layer 122 and in particular form electrical connections connected to the electronic components made in the first active layer 122.

The second level 116 is made with a second SOI substrate comprising a second support layer 126 comprising for example silicon, a second buried dielectric layer 128 comprising for example SiO₂ and a second semiconducting active layer 130, for example made of silicon. Electronic components, particularly FDSOI type FET transistors, are made in the second active layer 130. In particular, these other electronic components form the matrix 102 of memory cells, the back-bias circuit 106 and the word lines driver circuit 112. Several metallic interconnection layers 131 are made above the second active layer 130 and in particular make the electrical connections connected to the electronic components made in the second active layer 130.

Details of the manufacture of such a 3D circuit are given in the document “Design Technology Co-Optimization of 3D-monolithic standard cells and SRAM exploiting dynamic back-bias for ultra-low-voltage operation” by F. Andrieu et al., 2017 IEEE International Electron Devices Meeting (IEDM). Doped semiconducting wells forming ground planes of transistors of memory cells are made in the second support layer 126 and are designated as reference 132 on FIG. 2. Electrically conducting vias 134 make the electrical connections between the two levels 114 and 116. Given the density at which the memory cells 102 are made in the second active layer 130, the metallic interconnection layers 131 of the level 116 in which the matrix 102 of memory cells is made do not provide sufficient space to make the first and second coupling elements 108, 110. The metallic interconnection layers of another level of the circuit, in this case the layers 124 of the lower level 114, are used to make these coupling elements 108, 110.

In the example embodiment described herein, the first coupling elements 108 comprise portions of one of the metallic interconnection layers 124 of the lower level 114 that corresponds to the layer that is closest to the upper level 116 and that is called the last metallic interconnection layer (and that is marked as reference 133 on FIG. 2), and the second coupling elements 110 comprise portions of another of the metallic interconnection layers 124 of the lower level 114 that is located between the last metallic interconnection layer 133 and the other metal interconnection layers 124 and that is called the last but one, or penultimate, metallic interconnection layer (and that is marked as reference 135 on FIG. 2). For example, if the lower level 114 comprises six superposed metallic interconnection layers 124, the first metallic interconnection layer being the layer closest to the first active layer 122 and the sixth or last metallic interconnection layer being the layer furthest from the first active layer 122, the first coupling elements 108 are made in the sixth or last metallic interconnection layer and the second coupling elements 110 are made in the fifth or the penultimate metallic interconnection layer.

As a variant, it is possible that the electronic components made, in the above example, in the first active layer 122 and forming different circuits of the memory device 100 (line decoder, read amplifiers, etc.) are made in the second active layer 130, with the other elements forming the memory device 100.

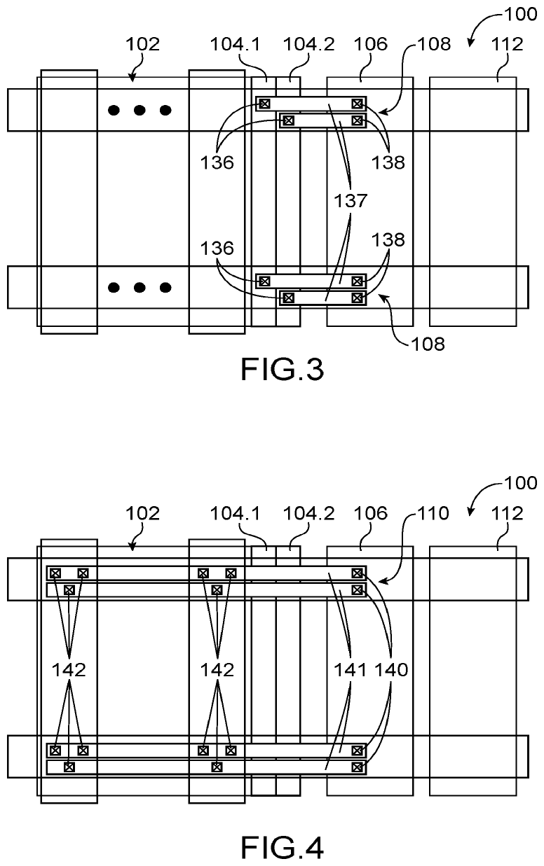

FIG. 3 is a view of the device 100 on which the first coupling elements 108 connecting the memory dots of the memory cells of columns 104 (in other words the cells forming the back-bias control bits) of two rows of the matrix 102 to the back-bias circuit 106 can be seen. These first coupling elements 108 comprise metallic portions 137 of one of the metallic interconnection layers 124, for example the last metallic interconnection layer 133, conducting vias 136 connecting the memory dots of these memory cells 102 to these metallic portions 137, and conducting vias 138 connecting these metallic portions 137 to inputs of the back-bias circuit 106. On the example embodiment shown on FIG. 3, given that the back-bias control bits are formed by the cells of the two columns 104.1 and 104.2, two first coupling elements 108 are used for each row of the matrix 102, each of these first coupling elements 108 being connected to one of the memory cells of these two columns 104.1 and 104.2.

FIG. 4 is a view of the device 100 showing the second coupling elements 110 connecting the back-bias circuit 106 to the doped semiconducting wells of the transistors of memory cells of the matrix 102 forming the data memorization bits, for two rows of the matrix 102. These second coupling elements 110 comprise metallic portions 141 of one of the metallic interconnection layers 124, for example the penultimate metallic interconnection layer, conducting vias 140 connecting outputs from the back-bias circuit 106 (on which the back-bias voltages are output) to the metallic portions 141, and conducting vias 142 connecting the metallic portions 141 to the doped semiconducting wells of the transistors of cells forming the data memorization bits of the associated row. On the example in FIG. 4, the transistors of each of the memory cells together comprise three wells, one being P doped and located under the active zones of the PMOS transistors and the other two being N doped and located under the active zones of the NMOS transistors. Considering that the back-bias voltages applied on the N doped semiconducting wells are different from those applied on the P doped semiconducting well, two second coupling elements 110 are used for each row of the matrix 102, one making the connection between the back-bias circuit 106 and the N doped semiconducting wells and the other making the connection between the back-bias circuit 106 and the P doped semiconducting well 106.

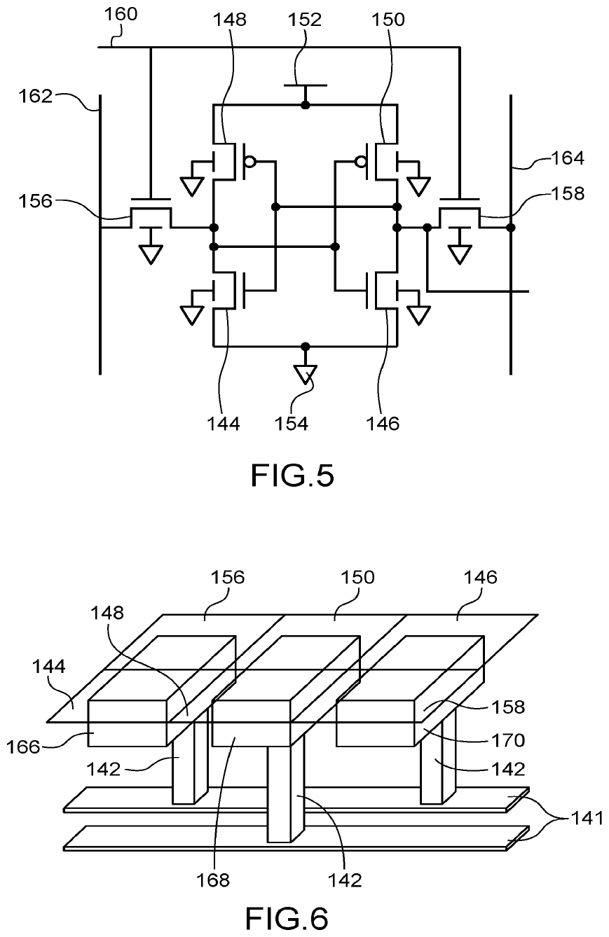

FIG. 5 shows an example embodiment of a 6T-SRAM type memory cell for which the active zones of transistors are formed above three semiconducting wells doped as in the example in FIG. 4, in other words with one P doped semiconducting well and two N doped semiconducting wells.

On FIG. 5, the memory cell comprises two NMOS transistors 144, 146, called “pull-down” transistors, and two PMOS transistors 148, 150, called “pull-up” transistors, together forming two inverters mounted head-foot and that define the memory dot of the cell. These two inverters are connected to an electric power supply terminal 152 onto which a power supply potential V_{DD} is applied, for example equal to about 1 V, and to a reference potential 154 GND corresponding for example to the ground of the memory device 100. The memory cell also comprises two access transistors 156, 158, also called “pass-gate” transistors, in this case of the NMOS type, having their gate connected to a word line 160 on which a signal controlling a read or a write in the memory cell will transit. The drains of the access transistors 156, 158 are connected to bit lines 162, 164 on which data to be memorized or to be written will transit, and their source is connected to inverters formed by the transistors 144, 146, 148 and 150.

FIG. 6 diagrammatically shows a configuration of doped semiconducting wells making back-bias possible of the transistors of the memory cell previously described with reference to FIG. 5.

On FIG. 6, the locations of the transistors of the memory cell are symbolically represented by rectangles with the same references as the transistors previously described with reference to FIG. 5. A first N-doped semiconducting well 166 enables back-bias of the transistors 144 and 156 that are both N type. A second P-doped semiconducting well 168 enables back-bias of the transistors 148 and 150 that are both P type. A third N-doped semiconducting well 170 enables back-bias of the transistors 146 and 158 that are both N type. The two N-doped semiconducting wells 166 and 170 are connected to one of the metallic portions 141 and the P-doped semiconducting well 168 is connected to the other of the metallic portions 141. The electrical connections between the wells 166, 168, 170 and the portions 141 are made by semiconducting vias 142.

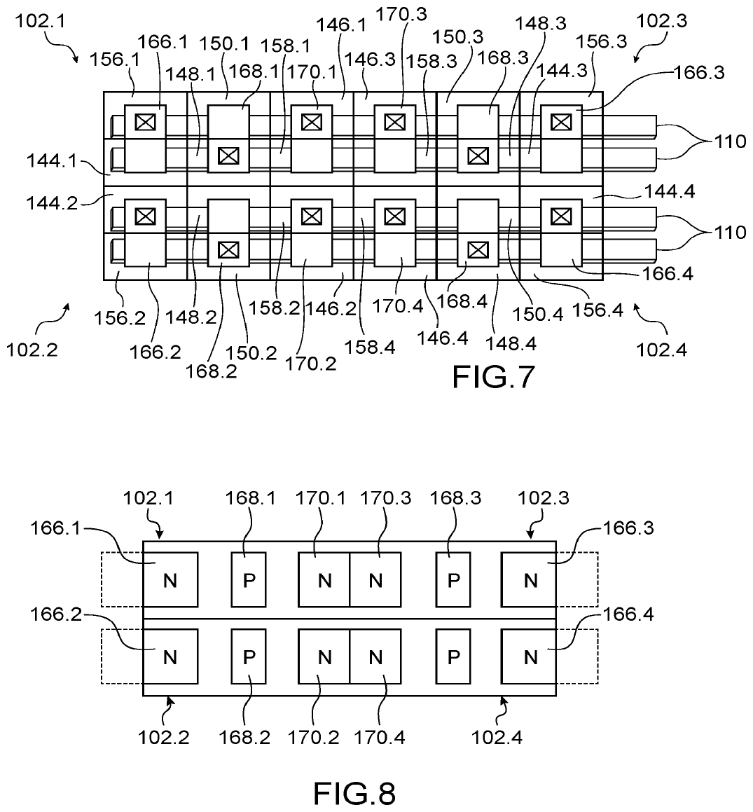

According to one advantageous embodiment, the memory cells forming the data memorization bits may be arranged by forming groups of four juxtaposed memory cells distributed on two rows and two columns of the matrix such that the transistors of the two cells located on the first of the two rows are arranged symmetrically with the transistors of the two cells located on the second of the two rows, and such that the transistors of the two cells located on the first of the two columns are arranged symmetrically with the transistors of the two cells located on the second of the two columns. FIG. 7 diagrammatically shows such an arrangement of the transistors in the four memory cells 102.1 to 102.4, and the distribution of the doped semiconducting wells enabling back-bias of these transistors. On FIG. 7, the same references as those shown on FIG. 6 are used with the addition of the number 0.1, 0.2, 0.3 or 0.4 depending on the memory cell to which the referenced element belongs.

In the memory device 100 as described previously, the back-bias of the transistors in the memory cells of the matrix 102 forming data memorization bits is independent for each of the rows of memory cells. To achieve this, the doped semiconducting wells through which back-bias is applied for transistors of memory cells located on two adjacent rows do not touch each other and are not electrically connected to each other. On the other hand, it is possible for wells belonging to two adjacent columns comprising a semiconductor doped with the same type of doping and that are located side by side, should be formed by the same portion of doped semiconductor. FIG. 8 diagrammatically shows such a configuration in which each of the N-doped semiconducting wells 166 and 170 of a first memory cell is formed by a portion of semiconductor common to another N-doped semiconducting well 166 or 170 of a second memory cell adjacent to the first memory cell.

As a variant, the semiconducting wells doped with the same type of conductivity (wells 166 and 170 in the previous example) may be connected to different metallic portions 110, each pair of transistors of the same type being associated with one of these metallic portions 110.

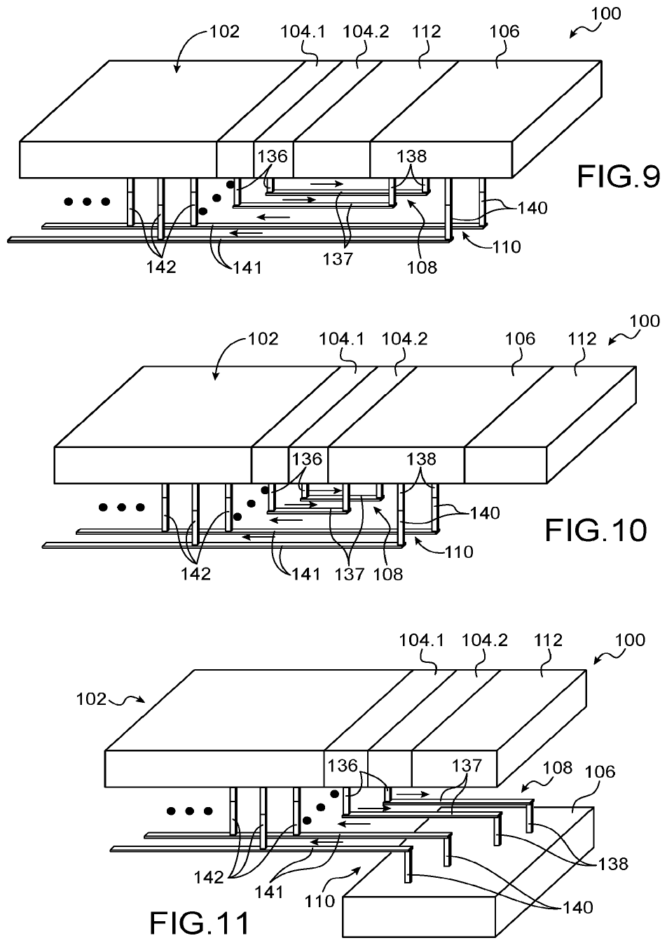

FIGS. 9 and 10 diagrammatically show example embodiments of the memory device 100 in which the matrix 102 of memory cells and the circuits 106 and 112 are made in the same active layer (for example the active layer 130 shown on FIG. 2), with the first and second coupling elements 108, 110 comprising metallic portions 137, 141 formed from the same metallic interconnection layer. The difference between these two example embodiments shown on FIGS. 9 and 10 relates to the position of circuits 106 and 112 relative to each other: on FIG. 9, the word lines driver circuit 112 is located between the matrix 102 of memory cells and the back-bias circuit 106, and on FIG. 10, the back-bias circuit 106 is located between the matrix 102 of memory cells and the word lines driver circuit 112.

FIG. 11 shows another example embodiment of the memory device 100 in which the back-bias circuit 106 is formed in another active layer (for example the active layer 122 shown on FIG. 2) located under the layer (for example the active layer 130 shown on FIG. 2) in which the matrix 102 of memory cells and the word lines driver circuit 112 are located.

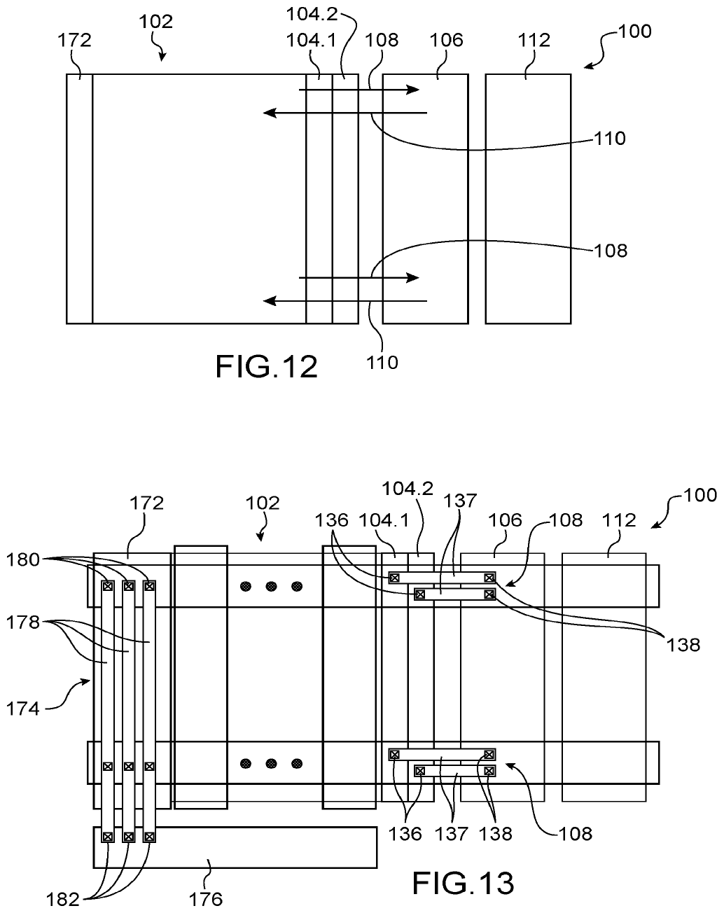

FIG. 12 diagrammatically shows a second embodiment of the memory device 100.

As in the first embodiment, the memory device 100 comprises the matrix 102 of SRAM type memory cells in which the memory cells of one or several columns 104 form back-bias control bits used to memorize the back-bias states of the other memory cells of the matrix 102 forming data memorization bits.

In this second embodiment, the memory cells of at least one column 172 correspond to end of read control bits. On the example embodiment shown on FIG. 12, the column 172 forms the left edge of the matrix 102, while the columns 104 form the right edge of the matrix 102. In general, the column 172 for which the memory cells form end of read control bits is chosen such that this column 172 is the column furthest from the line decoder associated with the matrix 104 and that in this case is on the side of the columns 104.

The semiconductor wells doped with the same type as transistors of memory cells of column 172 are electrically coupled to each other by third coupling elements, not shown on FIG. 12. These third coupling elements comprise in particular portions of one of the metallic interconnection layers, advantageously of the last metallic electrical interconnection layer 133 (that closest to the active layer in which the matrix 102 was made) that extend vertically to connect all semiconducting wells doped with the same type of conductivity as that present on the column 172 (unlike the doped semiconducting wells of the other memory cells of the matrix 102 that are coupled by row). In particular, this is the reason why column 172 is chosen as being the furthest from the row decoder associated with the matrix 102 and that is on the side of the columns 104.

The memory cells of column 172 are coupled to a circuit of the device 100, not shown on FIG. 12, that controls end of read of the data memorization bits. These memory cells of column 172 make it possible to detect the optimum instant at which a read must be made, in other words the moment at which the discharge of current in one of the bit lines is sufficient to enable error-free read of data stored in the data memorization bits. Depending on the number of simultaneously active memory cells of the column 172, a complete discharge of bit lines of these cells makes it possible to define an end of read for memory cells forming data memorization bits. The memory cells of column 172 comprise access transistors, the gates of which are coupled to the same word line distinct from those to which the gates of access transistors of memory cells forming data memorization bits are coupled.

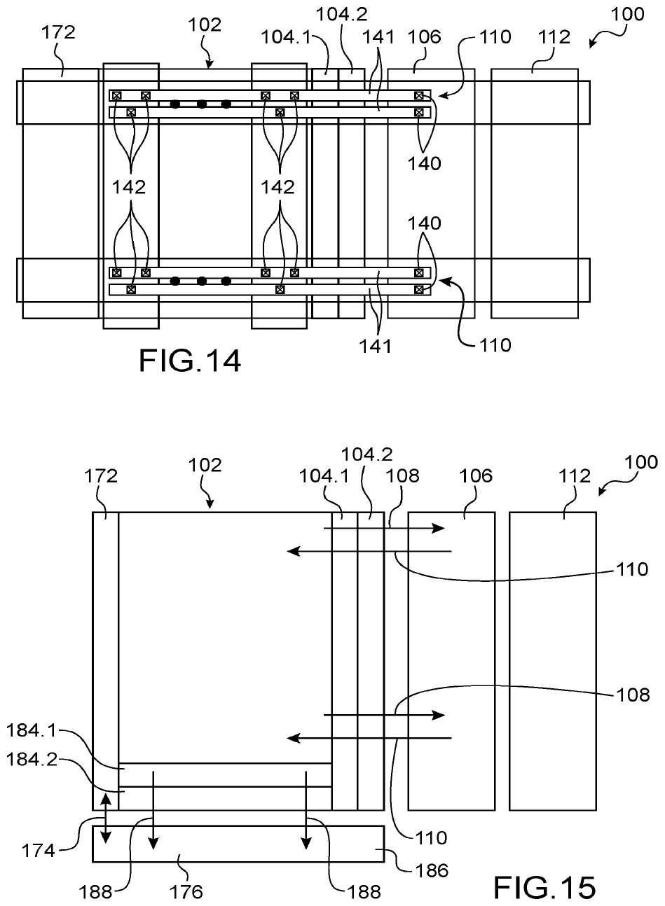

FIGS. 13 and 14 show an example embodiment of coupling elements of the memory device 100 according to this second embodiment.

FIG. 13 shows different coupling elements of the memory device 100 according to the second embodiment that are made in the last metallic interconnection layer, in the case the first coupling elements 108 and the third coupling elements 174. In this case, the first coupling elements 108 are similar to those previously described with reference to FIG. 3. In this second embodiment, the third coupling elements 174 connect the doped semiconducting wells of the memory cells in column 172 to another back-bias circuit 176 applying the back-bias voltages required for the cells in column 172. The third coupling elements 174 comprise metallic portions 178 of the last metallic interconnection layer and electrically conducting vias 180 connecting the metallic portions 178 to the doped semiconducting wells of memory cells in column 172 and electrically conducting vias 182 connecting the metallic portions 178 to the back-bias circuit 176.

FIG. 14 shows coupling elements of the device 100 according to the second embodiment that are made in the penultimate metallic interconnection layer, in this case the second coupling elements 110. In this case, the second coupling elements 110 are similar to those previously described with reference to FIG. 4.

According to one variant embodiment of the second embodiment described above, the third coupling elements 174 may be made in the same metallic interconnection layer as that in which the second coupling elements 110 are made, for example the penultimate metallic interconnection layer.

FIG. 15 shows a third embodiment of a memory device 100.

In this third embodiment, the matrix 102 comprises all elements previously described with reference to the second embodiment, particularly columns 104 and 172. Furthermore, one or several rows 184 of memory cells of the matrix 102 form second back-bias control bits in which are memorized the back-bias states of transistors of an inputs/outputs block 186 of the device 100 to which the columns of matrix 102 are connected. On the example in FIG. 15, the memory cells of the two rows 184.1 and 184.2 that form the lower edge of the matrix 102, correspond to these second back-bias control bits.

Fourth coupling elements 188 electrically couple the memory dots of memory cells of rows 184 to a second back-bias circuit, for example included in the inputs/outputs block 186, and configured to output back-bias voltages with values that depend on the values stored in the second back-bias control bits. The second back-bias circuit is coupled to doped semiconducting wells of FET transistors forming part of the block 186. These transistors correspond, for example, to the transistors of one or several of the circuits to which the columns of the memory cells of the matrix 102 are connected, either independently of each other or in groups; bit line precharge circuit of the matrix 102, multiplexer circuits, detection amplifiers, write/read assist circuit, or any other circuit forming part of the block 186.

In this third embodiment, the back-bias of transistors in the inputs/outputs block 186 can be precisely adjusted, making it possible for example to accelerate or retard read or write operations independently for each column in the matrix 102.

On FIG. 15, the inputs/outputs block 186 and the back-bias circuit 176 that is coupled to the memory cells of the column 172 are shown in the form of a single element.

According to one example of this third embodiment, when the memory device 100 is in a MUX4 type memory configuration (each input/output of the block 186 is coupled to four columns of memory cells of the matrix 102 through a multiplexer, as is the case for example for a matrix 102 comprising 128 columns and memorizing 32-bit words in each line) and when the matrix 102 comprises two rows 184, one of these two rows 184 may be used to memorize bias states to accelerate or not accelerate the transistors of one or several circuits connected to one of the four columns, and the second row 184 may be used to memorize the back-bias states of the transistors of one or several circuits shared by the four associated columns, on four bits (because each input/output of the block 106 is coupled to four columns), or to use a different bit for each of these circuits: for example one bit dedicated to the back-bias of the transistors of the detection amplifier, one bit dedicated to the “write assist” block, one bit dedicated to the data memorization block, and a last bit for the buffer circuit. These four bits may also be used to select a back-bias voltage common to all these circuits among several bias voltages with different values generated by a bias voltages generation circuit. According to another example, since the back-bias of NMOSs is different from that of PMOSs, it is possible to have four bits used to accelerate or retard the precharge circuit associated with each column, another bit used globally for NMOS transistors of multiplexer devices, another bit used globally for PMOS transistors of multiplexer devices, another used for NMOS transistors of detection amplifiers, and a last bit used for PMOS transistors of detection amplifiers.

The above paragraph is also applicable for a number of shared columns not equal to 4.

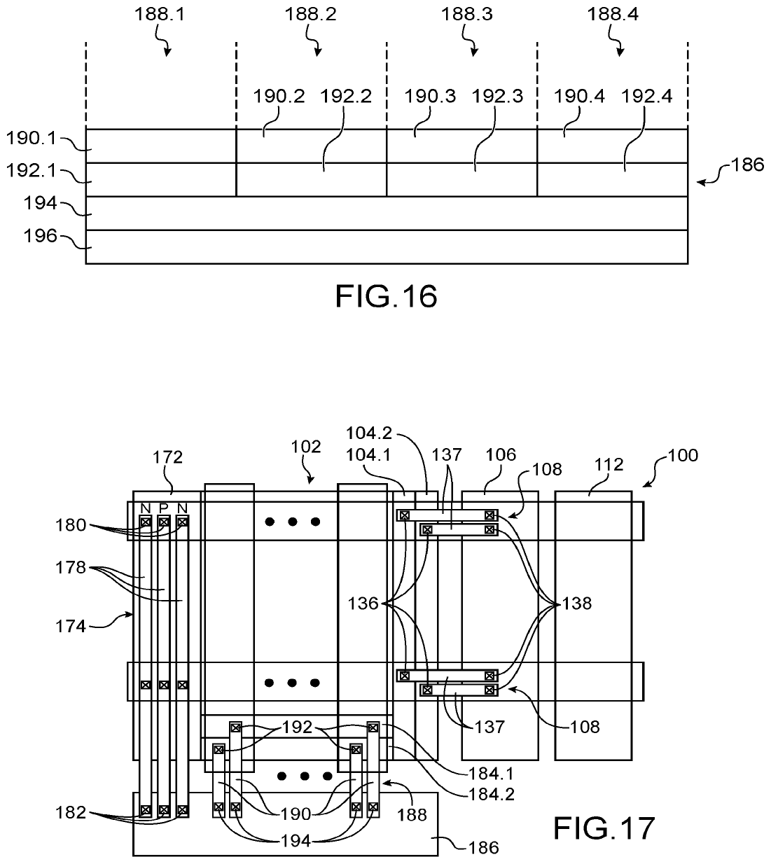

FIG. 16 diagrammatically shows this configuration in which four columns 188.1, 188.2, 188.3 and 188.4 of memory cells of the matrix 102 forming data memorization bits are connected to the inputs/outputs block 186. Each column 188.1-188.4 is coupled to a precharge circuit 190 (190.1 to 190.4 on FIG. 16) and to a read/write multiplexer 192 (192.1 to 192.4 on FIG. 16). Finally, the four columns 188.1-188.4 of memory cells of matrix 102 are connected to a detection amplifier 194 and to a write/read assist circuit 196 common to these four columns 188.1-188.4.

FIG. 17 shows an example embodiment of coupling elements formed in one of the metallic interconnection layers of the memory device according to the third embodiment. In this example embodiment, the fourth coupling elements 188 are made in the same metallic interconnection layer, advantageously the last metallic interconnection layer, as that in which the first and third coupling elements 108, 174 are made. The fourth coupling elements 188 comprise portions 190 of this metallic interconnection layer, electrically conducting vias 192 electrically coupling memory dots of transistors of cells in rows 184 to portions 190, and electrically conducting vias 194 electrically coupling the portions 190 to the second back-bias circuit included in this case in the block 186. The second coupling elements 110, not shown on FIG. 17, comprise metallic portions of another metallic interconnection layer, for example the penultimate metallic interconnection layer.

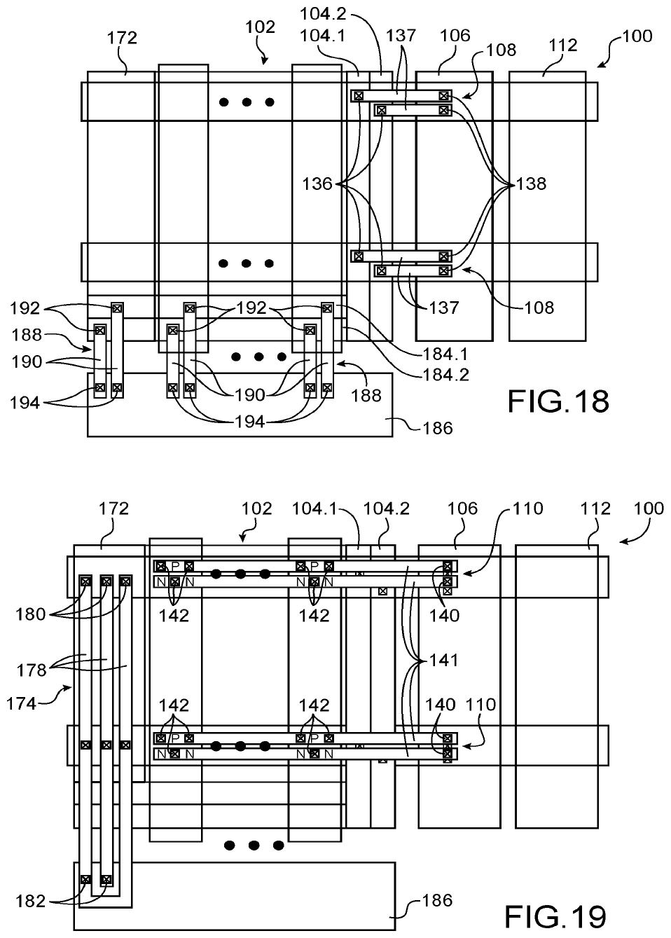

FIGS. 18 and 19 show a variant of the third embodiment. In this variant, the rows 184 are also used to store the back-bias states of transistors in column 172. FIG. 18 shows the coupling elements made in the last metallic interconnection layer, and FIG. 19 shows the coupling elements made in the penultimate metallic interconnection layer.

In the example embodiments of the three previously described embodiments, each memory cell comprises wells doped according to the two conductivity types N and P. Thus, for each row of memory cells in the matrix 102, two metallic portions are used to make connections to back-bias wells of the transistors in each memory cell. As a variant, if each memory cell comprises transistors including one or several semiconducting wells doped with a single conductivity type N or P, a single metallic portion 141 may be made to form the coupling element associated with each row of memory cells.

Furthermore, if a single bias control bit is used for each row of the matrix 102 to determine the value of the bias voltage to be applied to the wells in this row, each of the first coupling elements 108 associated with a row of the matrix 102 may comprise a single metallic portion 137.

Depending on the number of metallic portions used and the space available within the metallic interconnection layers, a single metallic interconnection layer may be used to form the metallic portions of the first and second coupling elements 108, 110, as is the case in the example embodiments previously described with reference to FIGS. 9 and 10. For example, if the available surface area for each row of memory cells makes it possible to have two metallic portions for each row, and if a single bias control bit is used for each row of memory cells and only one type of back-bias well is used for each memory cell, the first and second coupling elements may comprise metallic portions originating from the same metallic interconnection layer, advantageously the last metallic interconnection layer.

According to another variant, more than two metallic interconnection layers may be used to form the different metallic portions forming part of the different coupling elements of the device 100.

In all previously described embodiments, the first and second coupling elements comprise portions of metallic interconnection layers located between the two active layers 122, 130. As a variant, it is possible that only the first coupling elements or only the second coupling elements comprise portions of at least one metallic interconnection layer located between the two active layers 122, 130, and the other coupling elements comprise portions of a metallic interconnection layer 131 located above the active layer 130.

In general, the memory cells of the columns 104 and possibly the column 172 occupy the smallest possible surface area, and preferably have transistors similar to those of the other memory cells forming the data memorization bits of the matrix 102. These transistors are preferably arranged in a manner similar to the transistors of the other memory cells.

Furthermore, the arrangement of the transistors of the memory cells of columns 104 is such that the electrically conducting vias 136, which are connected to the memory dots of these cells, are connected to these memory dots through portions of polysilicon forming the gates of transistors that are connected to these memory dots. Thus, no surface area is lost due to the connections of electrically conducting vias of coupling elements to the memory dots of the memory cells, the surface area occupied by the memory cells of columns 104 possibly being similar to the surface area of the other memory cells of the matrix 102.

Regardless of the manufacturing method considered, the back-bias of the memory cells made within the memory device 100 makes it possible to detect errors and to make a self-correction of these errors. For example, for a read and/or write error detected on a word or a column, an improvement or a degradation of the performances of the memory cell(s) in which the error occurs may be made by modifying the back-bias of the transistors of these memory cells. Similarly, the read duration of the memory cells may be adjusted if a column of memory cells is dedicated to an end of read detection.

In all the previous embodiments and examples, the principle of adjusting the back-bias of one or several FET transistors may be applied for memory cells that may be of the SRAM, or CAM type, or TCAM, or even DRAM or ROM types when these cells comprise at least one FET transistor.

In the devices 100 described above, the 3D circuit forming the memory device 100 is such that the first active layer 122 forms part of a substrate comprising the support layer 118, the first active layer 122 being located between the support layer 118 and the second active layer 130.

In the previously described devices 100, the coupling elements 108, 110 comprise metallic portions 137, 141 of at least one of the metallic interconnection layers 133, 135 forming part of the BEOL (“Back-End Of Line”), of the first level 114, made on the first active layer 122.

In the previously described embodiments and variants of the memory device 100, the electrically conducting back-bias elements 166, 168, 170 of the transistors 144, 146, 148, 150, 156, 158 of memory cells forming the data memorization bits are located between the metallic portions 137, 141 of the coupling elements 108, 110 and the second active layer 130. In the example embodiment of FIG. 2, the support layer 126 of the substrate including the second active layer 130 is located between the second active layer 130 and the first active layer 122. As a variant, the second active layer 130 may be located between the electrically conducting back-bias elements 166, 168, 170 and the metallic portions 137, 141 of the coupling elements 108, 110, or the second active layer 130 may be located between the support layer 126 and the first active layer 122. Such a variant may be obtained by making the first and the second levels 114, 116 separately, then firmly securing them such that the metallic interconnection layers 131 of the BEOL of the second level 116 are located on the same side as the metallic interconnection layers 124 of the BEOL of the first level 114.

### DOCUMENTS MENTIONED

S. Nalam et al., “5T SRAM With Asymmetric Sizing for Improved Read Stability”, IEEE Journal of Solid-State Circuits, Vol. 46, No. 10, October 2011.
L. Chang et al., “An 8T-SRAM for Variability Tolerance and Low-Voltage Operation in High-Performance Caches”, IEEE Journal of Solid-State Circuits, Vol. 43, No. 4, April 2008.
I. J. Chang et al., “A 32 kb 10T Sub-Threshold SRAM Array With Bit-Interleaving and Differential Read Scheme in 90 nm CMOS”, IEEE Journal of Solid-State Circuits, Vol. 44, No. 2, February 2009.
F. Andrieu et al., “Design Technology Co-Optimization of 3D-monolithic standard cells and SRAM exploiting dynamic back-bias for ultra-low-voltage operation”, 2017 IEEE International Electron Devices Meeting (IEDM).

1. A memory device comprising at least:
a matrix of several rows and columns of memory cells forming data memorization bits, each of the memory cells comprising at least one FET transistor including at least one electrically conducting back-bias element, the matrix also comprising at least one column of memory cells forming first back-bias control bits;
a first back-bias circuit configured to output first back-bias voltages, the values of which depend on the values of first back-bias control bits;
first coupling elements, electrically coupling memory dots of memory cells forming the first back-bias control bits with the first back-bias circuit;
second coupling elements, electrically coupling the first back-bias circuit with electrically conducting back-bias elements of memory cells forming the data memorization bits;
and wherein:
the memory device forms a 3D circuit comprising at least first and second semiconducting active layers between which several metallic interconnection layers are stacked;
the first and/or the second coupling elements comprise metallic portions of at least one of the metallic interconnection layers.

2. The memory device according to claim 1, wherein the matrix is made in the second active layer, and the first back-bias circuit is made in at least one of the first and second active layers.

3. The memory device according to claim 1, wherein the first active layer forms part of a substrate comprising a support layer, the first active layer being located between the support layer and the second active layer.

4. The memory device according to claim 1, wherein:
the first coupling elements comprise metallic portions of one of the metallic interconnection layers called the last metallic interconnection layer and that corresponds to the layer among said metallic interconnection layers that is closest to the second active layer, and the second coupling elements comprise metallic portions of one of the metallic interconnection layers called the penultimate metallic interconnection layer and that is arranged between the last metallic interconnection layer and all the other metallic interconnection layers, or
the first and/or the second coupling elements comprise metallic portions of the last metallic interconnection layer.

5. The memory device according to claim 1, wherein the electrically conducting back-bias elements are independent from one row of memory cells to the next.

6. The memory device according to claim 1, wherein the electrically conducting back-bias elements comprise doped semiconducting wells.

7. The memory device according to claim 6, also comprising several word lines such that the memory cells forming the data memorization bits and arranged on the same row of the matrix comprise access transistors, the gates of which are coupled to the same word line, and wherein the semiconducting wells doped with the same type of conductivity and included in the transistors of memory cells in the same row of the matrix are electrically coupled to each other and to at least one output of the first back-bias circuit by at least one of the second coupling elements such that the same back-bias voltage are applied on said doped semiconducting wells.

8. The memory device according to claim 7, wherein the first back-bias control bits are formed by memory cells in one or several adjacent columns forming a first edge of the matrix, adjacent to which the first back-bias circuit is located.

9. The memory device according to claim 8, wherein:
the memory cells of at least one column forming a second edge of the matrix that is opposite the first edge of the matrix correspond to end of read control bits, the access transistors of which are coupled to at least one word line distinct from that to which the access transistors of the memory cells forming the memorization bits are coupled;
the memory cells forming the end of read control bits are electrically coupled to an end of read data memorization bits control circuit;
the semiconducting wells doped with the same type of conductivity and included in the transistors of memory cells forming the end of read control bits are electrically coupled to each other by third coupling elements comprising metallic portions of at least one of the metallic interconnection layers.

10. The memory device according to claim 9, wherein the metallic portions of the third coupling elements correspond to portions of the same metallic interconnection layer as that or one of those forming the metallic portions of the first and/or second coupling elements.

11. The memory device according to claim 1, also comprising:
at least one input/outputs block to which the columns of memory cells forming the data memorization bits are electrically connected;
a second back-bias circuit configured to output second back-bias voltages, the values of which depend on the values of second back-bias control bits formed by at least one row of the matrix;
fourth coupling elements, electrically coupling the memory dots of memory cells forming the second back-bias control bits with the second back-bias circuit, and comprising metallic portions of the same metallic interconnection layer as that or one of those forming the metallic portions of the first and/or second coupling elements;
and wherein the second back-bias circuit is coupled to electrically conducting back-bias elements of FET type transistors in the inputs/outputs block.

12. The memory device according to claim 11, wherein the second back-bias control bits are formed by memory cells in one or several adjacent rows forming a third edge of the matrix, adjacent to which the second back-bias circuit is located.

13. The memory device according to claim 9, also comprising:
at least one input/outputs block to which the columns of memory cells forming the data memorization bits are electrically connected;
a second back-bias circuit configured to output second back-bias voltages, the values of which depend on the values of second back-bias control bits formed by at least one row of the matrix;
fourth coupling elements, electrically coupling the memory dots of memory cells forming the second back-bias control bits with the second back-bias circuit, and comprising metallic portions of the same metallic interconnection layer as that or one of those forming the metallic portions of the first and/or second coupling elements;
and wherein the second back-bias circuit is coupled to electrically conducting back-bias elements of FET type transistors in the inputs/outputs block;
and wherein the third coupling elements electrically couple the electrically conducting back-bias elements of transistors of the memory cells of said at least one column forming the second edge of the matrix with the second back-bias circuit.

14. The memory device according to claim 1, wherein the memory cells of the matrix are of the SRAM, or CAM, or TCAM, or DRAM, or ROM type.
